(19) United States
(12) Patent Application Publication
(10) Pub. No.: US 2004/0113667 A1
(43) Pub. Date: Jun. 17, 2004

(54) Delay locked loop with improved strobe skew control

(76) Inventor: Huawen Jin, Plano, TX (US)

Correspondence Address: TEXAS INSTRUMENTS INCORPORATED, P O BOX 655474, M/S 3999, DALLAS, TX, 75265

(21) Appl. No.: 10/318,834

(22) Filed: Dec. 13, 2002

(51) Int. Cl. H03L 7/06

(52) U.S. Cl. 327/158

(57) ABSTRACT

The delay locked loop (DLL) with skew adjustment inside the DLL includes: a Phase Detector; a delay line (Delay Stage 1, Delay Stage 2, and Delay Stage M) having an input coupled to a clock reference CLKREF; a first skew adjustment device dT1 coupled between the clock reference CLKREF and a first input of the Phase Detector; a second skew adjustment device dT2 coupled between an output of the delay line and a second input of the Phase Detector; a Slave Delay Stage for providing a delay to a strobe signal DQS; and a control voltage source (Charge Pump and Loop Filter) coupled to an output of the Phase Detector for controlling the delay line and the Slave Delay Stage in response to the Phase Detector.

### FIELD OF THE INVENTION

This invention generally relates to electronic systems and in particular it relates to delay locked loops with improved strobe skew control.

### BACKGROUND OF THE INVENTION

Traditional prior art memory (DRAM) provides data output per each accessing clock cycle, either on the rising edge or falling edge. Double Data Rate memory (DDR) can provide valid data output on both rising and falling edges. If the accessing clock frequency remains the same, the equivalent data throughput is doubled, hence the name Double Data Rate memory.

In order for data to be securely accessed, DDR uses a different clock timing scheme from prior art memory design. A data strobe is assigned as associated with output data. The strobe is called DQS, as the data is called DQ. Initially, DQS is synchronized with DQ when data, either reading or writing, is transferred from/to the memory to/from memory controller. Assume the paths' delays are the same for DQ and DQS, DQ and DQS will arrive synchronized at the I/O ports of the block that uses them.

After DQ and DQS are imported, a special cell delays the DQS about 90 degrees (or ¼ of a cycle). By doing so, the DQS' rising/falling edge will be aligned in the center of the data DQ. Since aligning in the center provides the best chance for the DQS to catch DQ, it is desired in transmitting the data in DDR mode. Other delay amount may be possible, such as 72 degrees (or ⅕ of a cycle), but the principle will be the same.

To generate the timing delay, a special circuit is used. The requirement for the timing delay block is to follow any changes the external clock may have in the period or other aspects, hence a DLL (delay locked loop) is used. A DLL can follow and track an external reference clock. It usually contains several delay stages, assuming the number of stages is M. After the DLL is locked, the DLL will generate M different phases, which are evenly spaced within one clock cycle. Every phase has a (1/M)T phase lag from the one in front of it, with all phase lags adding to a full cycle period. Obviously, a 4-stage DLL (or any number as integer folds of 4) will generate a delay of (¼)T that the DDR application requires.

Timing skew describes the effect when two events happen that are not aligned in time, but have a small difference by measurement of correspondent edges. By assuming DQ and DQS arrive at the same moment at the input ports, they will be aligned correctly after DQS passes through the timing delay cell. However, there is no guarantee along the input or output paths the delay on DQ and DQS are identical. This will introduce skew in between them. The skew can be generated from differences in wire routes, bonding wire and lead frame differences, as well as test board differences. Hence skew adjustment is desired on the DQ and DQS paths.

A straightforward way to achieve the skew adjustment is shown in FIGS. 1A-1D. FIG. 1B shows the skew dt in DQ and DQS. FIG. 1C shows DQ and DQS after the Timing block has processed DQS. Since delay can only be added not subtracted, two skew adjustment blocks dT1 and dT2 are inserted in DQ and DQS paths with each block having delay of dT1 and dT2, respectively. By adjusting delays dT1 and dT2 properly, desired plus(delay)/minus(early) skew adjustment can be achieved. FIG. 1D shows DQ and DQS after delays dT1 and dT2 have adjusted the skew.

The drawback of this skew adjustment scheme is obvious. First, since DQ is composed of 8 or 16 bits, a large amount of hardware is needed to accomplish the adjustment. Because more blocks are inserted, timing budget will be further reduced by random jitter. Second, since DQS needs to sample DQ at around the middle point between two transition edges, maintaining 50/50 duty cycle on DQ and DQS is desired. This leaves quite stringent requirements on duty cycle performance from the skew adjustment blocks, which is not easily done. Third, any jitter degradation, caused by power supply bumping or other noise sources will have direct impact on output DQ/DQS.

### SUMMARY OF THE INVENTION

A delay locked loop (DLL) having skew adjustment inside the DLL includes: a phase detector; a delay line having an input coupled to a clock reference; a first skew adjustment device coupled between the clock reference and a first input of the phase detector; a second skew adjustment device coupled between an output of the delay line and a second input of the phase detector; a slave delay stage for providing a delay to a strobe signal; and a control voltage source coupled to an output of the phase detector for controlling the delay line and the slave delay stage in response to the phase detector.

### BRIEF DESCRIPTION OF THE DRAWINGS

In the drawings:

FIG. 1A is a diagram of a skew adjustment scheme;

FIGS. 1B-1D are timing diagrams of the skew adjustment scheme of FIG. 1;

FIG. 2 is a block diagram of a prior art delay locked loop;

FIGS. 3A and 3B are timing diagrams for the delay locked loop shown in FIG. 2; and

FIG. 4 is a block diagram of a preferred embodiment delay locked loop with skew adjustment built in.

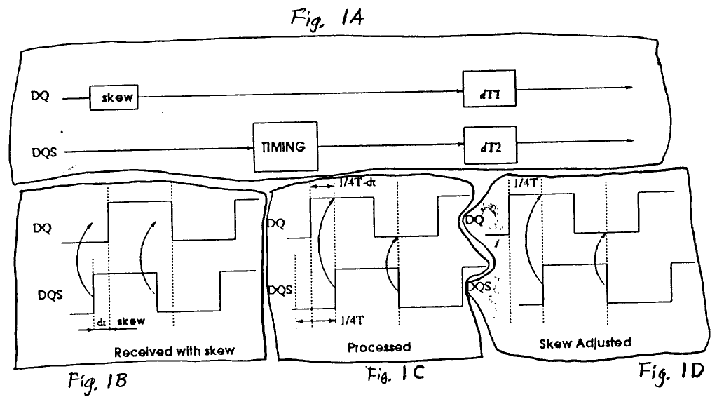

### DETAILED DESCRIPTION OF PREFERRED EMBODIMENTS

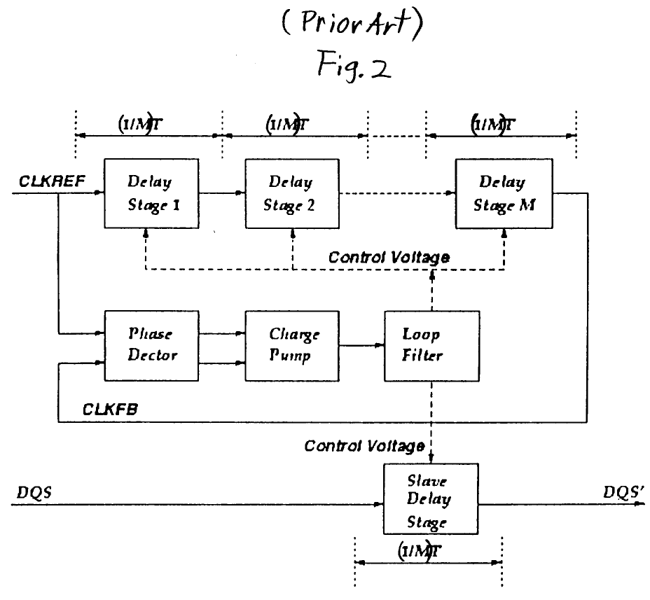

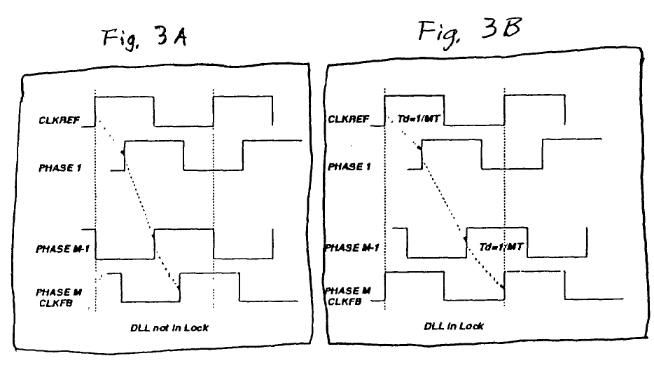

A prior art master/slave DLL architecture is presented before introducing the skew adjustment according to the present invention. FIG. 2 shows a typical prior art DLL block diagram used for DDR application. FIGS. 3A and 3B show the phase relationship of the DLL of FIG. 2. This DLL architecture has a main delay loop which is composed of Phase Detector which detects the phase difference between input reference clock CLKREF and the output feedback clock CLKFB from the last, delay stage; a control voltage source which includes: Charge Pump which charges/discharges the Control Voltage in response to the Phase Detector, and Loop Filter which provides filtering on Charge Pump, and is generally composed of capacitors; and a chain of delay stages (Delay Stage 1, Delay Stage 2, and Delay Stage M) that form a delay line. There is a replica Slave Delay Stage that is identical to one of the delay stages within the main delay loop.

Since the Slave Delay Stage is identical with the other delay stages in both structure and control, it will have the same delay performance as the other stages in the delay line. Once the delay line is locked with delay in each stage of (1/M)T, the slave delay will also be (1/M)T as desired.

The Phase Detector will force the loop to respond such that the two inputs to the Phase Detector will have zero phase difference. Since the Phase Detector's inputs are from reference clock CLKREF and feedback clock CLKFB, zero phase difference shows a full clock delay within the delay line. When that is achieved, a lock condition is reached. CLKREF and CLKFB will have exactly 2π phase shift even though they appear to overlap. When the Phase Detector's two inputs have difference, or offset, it indicates the total delay within the delay line is not equal to one full reference clock cycle. When CLKFB is later than CLKREF, longer delay (>(1/M)T) exists in the delay line, and when CLKREF is later than CLKFB, shorter delay (<(1/M)T) exists in the delay line. Under these two conditions, the Phase Detector will have a non-zero output to adjust the loop towards lock condition.

FIG. 3A shows CLKREF, PHASE 1 (output of Delay Stage 1), PHASE M-1 (output of Delay Stage M-1, not shown), and PHASE M (CLKFB) when the DLL is not in lock. FIG. 3B shows the signals of FIG. 3A when the DLL is in lock. In FIG. 3B PHASE 1 has a time delay Td of (1/M)T from CLKREF. Each additional PHASE up to PHASE M has a time delay Td of (1/M)T from the previous PHASE such that PHASE M has a 2π phase shift from CLKREF.

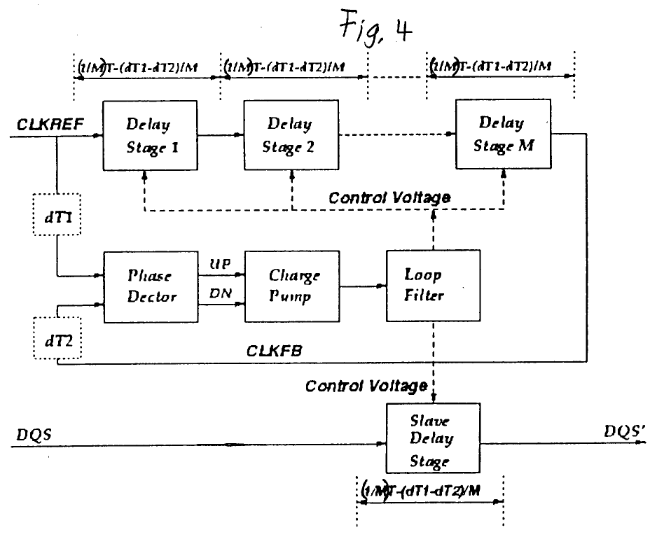

FIG. 4 is a diagram of a preferred embodiment DLL with skew adjustment built in. FIG. 4 is the same as FIG. 2 except that skew adjustment blocks dT1 and dT2 have been added. Instead of inserting skew adjustment blocks dT1 and dT2 on the output path, they are inserted in front of the inputs of the Phase Detector. The DLL reaches lock condition when the two inputs of the Phase Detector have zero phase difference, even though CLKREF and CLKFB may not have zero phase difference. This is equivalent to having a fixed timing offset existing in the system such that output delays from the delay stage are fixed to be shorter or longer than (1/M)T per stage. Since the Slave Delay Stage uses identical structure and control voltage, the Slave Delay Stage (hence the DQS delay) will have shorter or longer delay than (1/M)T as in the main loop.

By doing the procedure as stated, DQS will have an adjusted timing relationship with respect to DQ, or equivalent skew adjustment to compensate for timing differences arising elsewhere. On the other hand, since the DLL still will trace changes on the external reference clock CLKREF, the basic function of the DDR application will be the same except for the built-in skew.

For the preferred embodiment of FIG. 4, the calculated effective delay is presented. Assuming the two inserted blocks have delay of dT1 and dT2 respectively, each delay stage will have effective delay T_{d} of:

T_{d}=(1/M)T−(dT1−dT2)/M

The absolute adjusted skew T_{adj} will be:

T_{adj}=(dT1−dT2)/M

There are several benefits in doing skew adjustment according to the preferred embodiment method as compared to the prior art. First, only two adjustment blocks are needed versus 9 to 17. This greatly reduces hardware. Second, since adjustment is performed indirectly, the output will not have any duty cycle degradation. The Phase Detector uses single ended comparison and is immune to the duty cycle issue. Third, since the adjustment is performed within the loop, no direct jitter influence will be put on the output, which maintains the DLL jitter performance. Fourth, since the delay difference between dT1 and dT2 is divided by M, finer delay adjustment is obtained.

The total skew adjustment will be limited by number of stages and working frequency as the delay stage has minimum delay lower limits. However, it can be calculated that the range is generally large enough to handle many situations where skew adjustment is required.

The preferred embodiment provides a skew adjustment inside a DLL. It can be used in a DDR memory controller to compensate for trace delay difference. It can also be used in general DLL/PLL applications where fine delay/phase delay is required.

While this invention has been described with reference to an illustrative embodiment, this description is not intended to be construed in a limiting sense. Various modifications and combinations of the illustrative embodiment, as well as other embodiments of the invention, will be apparent to persons skilled in the art upon reference to the description. It is therefore intended that the appended claims encompass any such modifications or embodiments.

What is claimed is:

1. A delay locked loop comprising:
a phase detector;
a delay line having an input coupled to a clock reference;
a first skew adjustment device coupled between the clock reference and a first input of the phase detector;
a second skew adjustment device coupled between an output of the delay line and a second input of the phase detector;
a slave delay stage for providing a delay to a strobe signal; and
a control voltage source coupled to an output of the phase detector for controlling the delay line and the slave delay stage.

2. The device of claim 1 wherein the delay line comprises M delay stages, where M is an integer.

3. The device of claim 2 wherein each of the M delay stages provides a delay of (1/M)T−(dT1−dT2)/M, where T is a time length of a clock cycle of the clock reference, dT1 is a time delay provided by the first skew adjustment device, and dT2 is a time delay provided by the second skew adjustment device.

4. The device of claim 3 wherein the slave delay stage provides a delay of (1/M)T−(dT1−dT2)/M.

5. The device of claim 1 wherein the control voltage source comprises a charge pump coupled to the output of the phase detector.

6. The device of claim 5 wherein the control voltage source further comprises a loop filter coupled between the charge pump and the delay line.

7. The device of claim 2 wherein the control voltage source comprises a charge pump coupled to the output of the phase detector.

8. The device of claim 7 wherein the control voltage source further comprises a loop filter coupled between the charge pump and the M delay stages and between the charge pump and the slave delay stage.

9. A method for strobe skew control in a delay locked loop comprising:
inputting a reference clock signal into a delay line;
inputting the reference clock signal into a first skew adjustment device;
inputting an output clock signal from the delay line into a second skew adjustment device;
detecting a phase difference between an output of the first skew adjustment device and an output of the second skew adjustment;
providing a control signal to the delay line in response to the phase difference; and
providing a delay in a data strobe signal in response to the control signal.

10. The method of claim 9 further comprising providing M delay stages in the delay line, where M is an integer.

11. The method of claim 10 wherein each of the M delay stages provides a delay of (1/M)T−(dT1−dT2)/M, where T is a time length of a clock cycle of the reference clock signal, dT1 is a time delay provided by the first skew adjustment device, and dT2 is a time delay provided by the second skew adjustment device.

12. The method of claim 11 wherein the delay in the data strobe signal is (1/M)T−(dT1−dT2)/M.
